(19) United States
(12) Patent Application Publication
(10) Pub. No.: US 2023/0138317 A1
(43) Pub. Date: May 4, 2023

(54) SUBSTRATE PROCESS SYSTEM INCLUDING A COOLING STATION

(71) Applicant: Taiwan Semiconductor Manufacturing Company, Ltd., Hsinchu (TW)

(72) Inventors: Li-Chien Tseng, Hsinchu (TW); Ming-Shiou Kuo, Taichung City (TW)

(21) Appl. No.: 17/577,010

(22) Filed: Jan. 16, 2022

Related U.S. Application Data
(60) Provisional application No. 63/274,930, filed on Nov. 2, 2021.

(51) Int. Cl. C23C 16/46; C23C 16/458; H01L 21/02

(52) U.S. Cl. CPC C23C 16/463; C23C 16/4583; H01L 21/02263

(57) ABSTRACT

An apparatus for semiconductor processing is provided. The apparatus includes a housing comprising a plurality of shelves configured to receive a plurality of substrates; a shelter plate disposed over an upper side of the housing and configured to reduce heat loss of an upper substrate of the plurality of substrates; and an airflow structure in the housing and configured to control an air circulation in the housing.

### PRIORITY CLAIM AND CROSS-REFERENCE

The present application claims priority to U.S. Provisional Patent Application No. 63/274,930, filed on Nov. 2, 2021, and entitled “SUBSTRATE PROCESS SYSTEM INCLUDING A COOLING STATION,” the entire disclosure of which is incorporated herein by reference.

### BACKGROUND

Semiconductor devices are used in a variety of electronic applications, such as personal computers, cell phones, digital cameras, and other electronic devices. Semiconductor devices are fabricated by sequentially depositing insulating or dielectric layers, conductive layers, and semiconductor layers over a substrate, and patterning the various material layers using lithography to form circuit components and elements.

One of the important drivers for increased performance in semiconductor devices is the higher levels of integration of circuits. This is accomplishing by shrinking the device geometries or feature sizes. However, the widths of trench structures on the device become so narrow that filling such trench structures become problematic. One approach has been utilizing highly flowable precursor materials that may be applied in a liquid phase to a spinning substrate surface. These flowable precursors can flow into the trench structures. Once these flowable materials are deposited, they have to be cured into solid dielectric materials.

### BRIEF DESCRIPTION OF THE DRAWINGS

The present disclosure is best understood from the following detailed description when read with the accompanying figures. It is noted that, in accordance with the standard practice in the industry, various features are not drawn to scale. In fact, the dimensions of the various features may be arbitrary increased or reduced for clarity of discussion.

FIG. 1A is a simplified top plan view of a substrate process system according to an embodiment.

FIG. 1B is a graph illustrating the number of defects formed on a substrate as a function of idle time according to some embodiments.

FIG. 2A is a simplified top plan view of a curing chamber according to an embodiment.

FIG. 2B is a simplified cross-sectional view of the curing chamber of FIG. 2A.

FIG. 3A is a simplified cross-sectional view of a cooling station according to an embodiment.

FIG. 3B is a simplified top plan view of a cooling system according to an embodiment.

FIG. 3C is a simplified top plan view of a cooling system according to another embodiment.

FIG. 4A is a simplified cross-sectional view of a cooling station according to an embodiment.

FIG. 4B is a simplified cross-sectional view of a showerhead according to an embodiment.

FIG. 4C is a simplified cross-sectional view of a cooling station according to an embodiment.

FIG. 5 is a simplified flowchart of a process that may be utilized in a substrate process system according to an embodiment.

FIGS. 6A to 6C are simplified cross-sectional views of a portion of a substrate in various stages of the process illustrated in FIG. 5.

### DETAILED DESCRIPTION

The following disclosure provides many different embodiments or examples for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Prepositions, such as “on” and “side” (as in “sidewall”) are defined with respect to the conventional plane or surface being on the top surface of the wafer or substrate, regardless of the orientation of the wafer or substrate. The term “horizontal” is defined as a plane parallel to the conventional plane or surface of a wafer or substrate, regardless of the orientation of the wafer or substrate. The term “vertical” refers to a direction perpendicular to the horizontal as defined above, i.e., perpendicular to the surface of a substrate. The terms “first,” “second,” “third,” and “fourth” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Embodiments of the present disclosure relate to a cooling station, a system and method for controlling a temperature of a substrate or a batch of substrates (wafers) coming out of a process chamber to prevent vapor condensation from forming on the substrate or the batch of substrates. A substrate can include a single or multiple material layers to be patterned. The multiple material layers can include a silicon layer, a dielectric layer, an electrically conductive layer, and the like. When a flowable material is formed on the substrate by a flowable chemical vapor deposition (FCVD) process, the substrate including the flowable material formed (deposited) thereon is provided to a curing chamber where the formed flowable material is heated to form a cured material. In an exemplary embodiment, the flowable material can include TSA(SiH₃)₃N and NH₃. The cured material is then provided to a cooling station, where the cured material is cooled. However, it is observed that, in conventional systems, when the cured material is provided to an interface chamber having a room temperature (typically between 15° C. and 30° C.) in the fabrication facility in a transition period , with time passing, the low temperature (compared to the temperature in the curing chamber) in the interface chamber may gradually cause vapor of the cured material to condense, and the condensed vapor may deposit on the surface of the substrate, thus causing defects. In general, the amount of defects increases with the idle time during which the substrate with the cured flowable material remains in a cooling station.

For addressing the above-mentioned flowable film condense accumulation problem in the cooling station, embodiments provide a substrate process system including a novel cooling station that can reduce or eliminate defects associated with vapor condensation when transferring the cured substrates from the curing chamber to the cooling station, by setting the temperature of the cooling station to a predetermined or target temperature. In some implementations, the predetermined temperature is higher than the room temperature (typically between 15° C. and 30° C.) in the fabrication facility. In one example, the predetermined temperature is higher than 15° C. In other implementations, the predetermined temperature is close to that of the curing chamber or a process chamber (i.e., a chamber where the semiconductor processing is conducted). In some implementations, the predetermined temperature is between a temperature of the process chamber and a temperature of the curing chamber. As a result, the temperature gap between the cooling station and the curing chamber is narrowed, thus reducing or eliminating defects associated with vapor condensation when transferring the substrates. The novel cooling station can also operate as a temperature controller to bring the substrates to a predetermined temperature prior to placing the substrates to a transfer chamber that places the substrates to one or more process chambers using a robotic arm.

In some embodiments, a substrate process system is provided to include a novel cooling station that is configured to bring one or more substrates to a predetermined temperature prior to transferring the one or more substrates to a process chamber for processing and controlling a temperature of the one or more substrates after they have been processed to prevent vapor condensation from forming on the one or more substrates. The novel cooling station has several features that can be utilized individually or in combination, i.e., not all of the features described and illustrated herein are required to achieve the advantages and benefits of the cooling station in accordance with the present disclosure.

In some embodiments, the cooling station in accordance with the disclosure includes a housing, a wafer holder in the housing and including a plurality of lateral shelves configured to receive a plurality of substrates, a shelter plate mounted on an upper side of the housing and configured to reduce heat loss of an upper substrate that has been processed. The shelter plate thus serves as a passive heating member. In an embodiment, each lateral shelf of the wafer holder includes a heating element configured to control a temperature of a substrate disposed thereon. The wafer holder thus operates as an active heater for each individual substrate. In an embodiment, the cooling station can include an airflow structure configured to receive air from an inlet and control an air circulation of the cooling station. The airflow structure thus operates as a passive heater. In an embodiment, the housing of the cooling station includes a material having low thermal conductivity to reduce heat loss of the cooling station. These features can operate singly or in combination to control a temperature of a processed substrate to prevent condensed vapor formation. These and other embodiments of the disclosure, along with many of the advantages and features, are described in more detail in conjunction with the text below and corresponding figures.

The terms “substrate” and “wafer” are often used interchangeably in this field and are to be understood as including silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process may have been utilized to form regions or junctions in the base semiconductor structure or foundation. In addition, the semiconductor need not be silicon-based, but could be based on silicon-germanium, germanium, or gallium arsenide, and other. The terms “formed” and “deposited” are also used interchangeably herein.

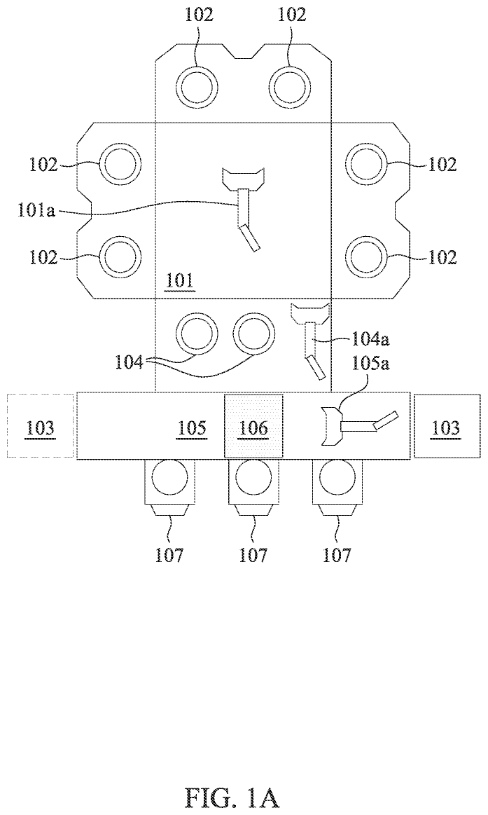

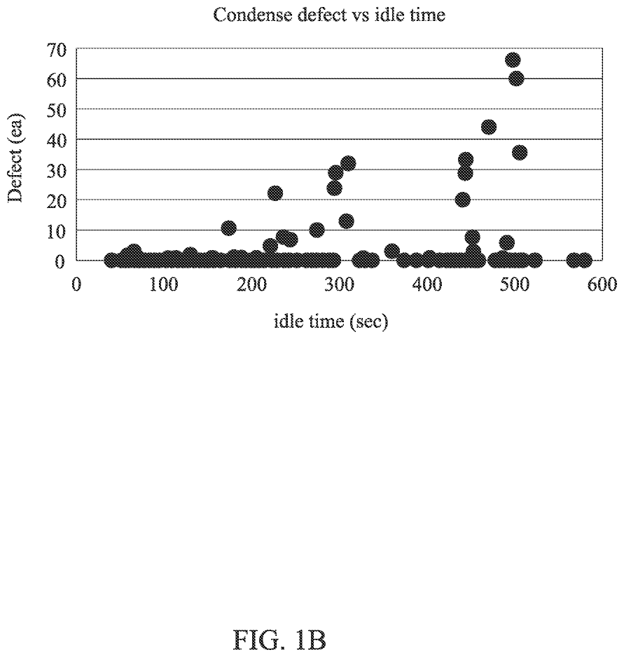

FIG. 1A is a simplified top view of a substrate process system 10 according to an embodiment. Referring to FIG. 1A, the substrate process system 10 includes a transfer chamber 101, one or more process chambers 102 connected to the transfer chamber 101 and configured to process substrates, a curing chamber 103 for curing substrates that have been processed, a load lock chamber 104 connected to the transfer chamber 101 and configured to transfer substrates without substantially affecting the air pressure therebetween, an interface chamber 105 connected to the load lock chamber 104, and a cooling chamber 106 disposed in the interface chamber 105 and in a vicinity of the curing chamber 103. The substrate process system 10 also includes one or more front opening unified pods (FOUPs) 107. In some embodiments, substrates are supplied from the FOUPs 107 to the interface chamber 105 by a first set of robotic arms 105a. The substrates are then supplied to the load lock chamber 104 by a second set of robotic arms 104a. The substrates are further supplied to the transfer chamber 101 by a third set of robotic arms 101a. The third set of robotic arms 101a are also configured to transport the substrates to the process chambers 102. The FOUPs 107 and the interface chamber 105 allow substrates to be loaded and unloaded without the load lock chamber 104, the transfer chamber 101, and the process chambers 102 to air. The pressure of the FOUPs 107 is usually at about 1 atm, i.e., same as the fab environment, whereas the pressure of the load lock chamber 104 is lower, e.g., less than about 10 Torr.

In operation, substrates are transferred into and out of the substrate process system 10, either individually or in batches via the FOUPs 107. The substrates are transferred from the FOUPs 107 to the load lock chamber 104 via the interface chamber 105, where they are isolated from the ambient environment. For example, an inert gas (e.g., nitrogen) is purged through the load lock chamber 104 which is pumped down to a low pressure to remove any air from the ambient environment. The substrates are transferred to the process chambers 102 that are also pumped down to a similar pressure to be in equilibrium of the load lock chamber 104 via the transfer chamber 101.

In an embodiment, the process chambers 102 each are configured to deposit a flowable dielectric material on a substrate. In the exemplary embodiment, three pairs of the process chambers 102 are used to deposit the flowable dielectric material on the substrate. For example, the flowable dielectric material can be formed on the substrate by a spin-on coating process. Flowable dielectric materials may include phospho-silicate glass (PSG), boron-silicate glass (BSG), boron-doped phospho-silicate glass (BPSG), undoped silicate glass (USG), or the like. In an embodiment, the substrates of the process chambers 102, after being processed, are placed into the curing chamber 103. The processed substrates each have the deposited flowable dielectric material deposited thereon. The curing chamber 103 can perform a curing process on a plurality of processed substrates. In an embodiment, the curing process includes heating the flowable dielectric material to react with precursors under a relatively high pressure, such that the precursors can react with the deposited flowable dielectric material. In some embodiments, the curing chamber 103 is configured to concurrently perform a curing process on the number of substrates that have been processed by the process chambers 102. In some other embodiments, the substrate process system 10 may have two individual curing chambers 103 disposed on opposite sides of the interface chamber 105 to accommodate the number of substrates that have been processed by the process chambers 102. In the embodiment of two curing chambers, the second curing chamber 103 is disposed on the left side of the interface chamber 105 (denoted by a dotted line box).

After the curing process, the cured substrates are then placed into the cooling station 106 that keeps the cured substrates to a predetermined temperature to prevent vapor condensation from forming on the surface of the cured substrates. As mentioned above, the vapor condensation typically results from the low temperature of the cooling station in conventional systems, and the condensed vapor may deposit on the surface of the substrates, thus causing defects. In an embodiment, the cooling station 106 is configured to perform a cooling process on the number of substrates that have been cured in the single curing chamber 103 or both the curing chambers 103 disposed on opposite sides of the cooling station 106. It is noted that the curing chamber 103 is a closed chamber, i.e., it is completely sealed while performing the curing process under a pressure that can be more than the atmosphere pressure, whereas the cooling station is an open system that operates at an ambient pressure or atmosphere pressure.

In an embodiment, each of the process chambers 102 can be set to a temperature that is sufficiently elevated to facilitate a flowable chemical vapor deposition (FCVD) process. In an embodiment, flowable dielectric material precursors may be silicon-containing precursors including silane, disilane, methylsilane, dimethylsilane, trimethylsilane, tetraethoxylane (TEOS), or combination thereof. In an embodiment, flowable dielectric material precursors may be silicon nitride containing precursors including sillylamine, trisillylamine (TSA) and disillylamine (DSA), or combination thereof. In an exemplary embodiment, the process chambers 102 can have a temperature in a range between 20° C. and 200° C., in a range between 30° C. and 100° C., in a range between 50° C. and 70° C. After depositing a flowable material layer onto the substrates, the thus processed substrates are provided to a curing chamber 103 that performs a curing process on the processed substrates. In an embodiment, the curing process can be performed at a temperature in a range between 20° C. and 200° C., in a range between 30° C. and 60° C. After the flowable dielectric material on the substrates has been cured, the cured substrates are then placed in the cooling station 106 that can have a predetermined temperature below a dew point temperature to prevent vapor condensation from forming on the surface of the cured substrates. In an embodiment, the predetermined temperature of the cooling station 106 can be controlled within a range between 0° C. and 40° C., in a range between 20° C. and 30° C.

In an embodiment, the cooled substrates in the cooling station 106 are then either supplied to the FOUPs 107 by the first set of robotic arms 105a, where they can be removed. In an embodiment, the cooled substrates in the cooling station 106 are placed back to the load lock chamber 104 by a second set of robotic arms 104a, where they will be provided to the process chambers 102 by the third set of robotic arms 101a for further flowable material deposition.

In an embodiment, the curing chamber 103 has a load lock atmospheric door that can be open to receive multiple processed substrates having a flowable material deposited thereon that is to be cured. In an embodiment, the cooling station 106 has a first access door that is configured to allow the first set of robotic arms 105a to place substrates from the FOUPs 107 to the cooling station 106. In an embodiment, the cooling station 106 also has a second access door that is configured to allow the second set of robotic arms 104a to place cured substrates from the curing chamber 103 to the cooling station 106. In an embodiment, the cooling station 106 further has a third access door that is configured to allow the third set of robotic arms 101a to place the cooled substrates from the cooling station 106 to the transfer chamber 101. In an embodiment, the cooling station 106 can have a single access door configured to receive substrates to be processed from the FOUPs 107 by the first set of robotic arms 105a, the cured substrates from the curing chamber 103 by the second set of robotic arms 104a, or place the cooled substrates to the transfer chamber 101 by the third set of robotic arms 101a. In this embodiment, the cooling station 106 can be rotated along a vertical axis in a rotational movement so that it faces the first, second, or third set of robotic arms, thereby allowing the reception or placement of the substrates from the FOUPs, the curing chamber or to the transfer chamber 101.

It should be noted that FIG. 1A illustrates a substrate process system 10 including three FOUPs 107, two load lock chambers 104, three pairs of process chambers 102, one curing chamber 103, and one cooling chamber 106. It is understood that other embodiments may include fewer or more FOUPs, load lock chambers, process chambers, curing chamber, and cooling chamber. Embodiments of the present disclosure may be utilized in other processing equipment, where it is desirable to control the temperature of a substrate as it is being transferred from a location to another location.

In some embodiments, the cooling station 106 is configured to store a total number of substrates that have been processed and cured. For example, when each process chamber 102 can process a batch of 25 substrates, the curing chamber 103 may have an integer number of curing sub-chambers or modules configured to receive and cure the total number of substrates that have been processed by the process chambers, and the cooling station 106 has a capacity of receiving and treating 150 (25×6) substrates concurrently. The present inventors have observed that a long idle time of the substrates in the cooling station 106 may induce defects in the substrates because vapor can be condensed onto particles that are then deposited on the surface of the substrates. FIG. 1B is a graph illustrating the number of defects formed on a substrate as a function of idle time according to some embodiments. Referring to FIG. 1B, the x-axis represents the idle time in seconds (sec) of a substrate in the cooling station, and the y-axis represents the number of defects due to vapor that is condensed onto particles that are then deposited on the substrate. The idle time refers to the time the substrate awaits further actions, such as removal from the substrate process system 10 through the interface chamber and the FOUPs, or retransfer back to the process chamber for further processing. As can be seen, the number of defects increases when the substrate idles in the cooling station between 180 seconds and 300 seconds, and between 450 seconds and 500 seconds. The present inventors provide the following technical solutions to reduce or eliminate such defect.

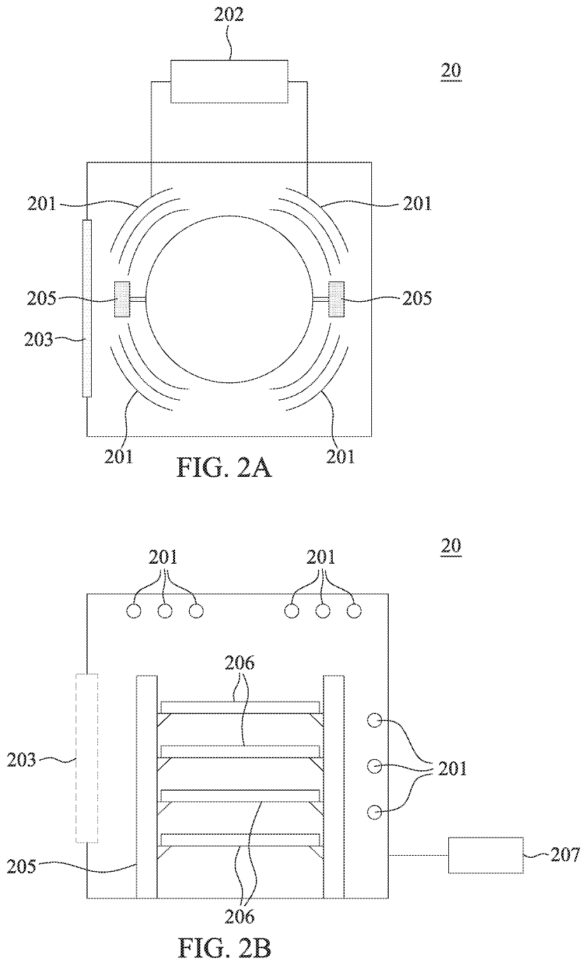

FIG. 2A is a simplified top plan view of a curing chamber 20 according to an embodiment. The curing chamber 20 may be the curing chamber 103 of FIG. 1, i.e., the curing chamber 20 is disposed in the vicinity of the cooling system 106 for transferring a substrate having a cured flowable dielectric material formed thereon. In an embodiment, the curing chamber 20 is configured to cure the flowable dielectric material in an atmosphere including ozone. Referring to FIG. 2A, the curing chamber 20 has a plurality of heating wires 201 coupled to a heating gas delivery system 202 and configured to control a curing temperature and atmosphere conditions of the curing chamber 20. In one implementation, the hearting wires 201 may be ceramic liners. In an embodiment, the heating gas delivery system 202 can control the temperature of the curing chamber from about 25° C. to about 200° C., from about 30° C. to about 60° C., and from about 40° C. to about 50° C. The curing chamber 20 has an access door 203 in communication with the load lock chamber 104 and the cooling station 106. Once the flowable dielectric material has been cured, the access door 203 is opened, the substrate including the cured flowable dielectric material is transferred to the cooling station 106 by the first set of robotic arms 105a.

FIG. 2B is a simplified cross-sectional view of the curing chamber 20 of FIG. 2A. Referring to FIG. 2B, the curing chamber 20 includes a substrate rack 205 configured to support a plurality of processed substrates 206 that include a flowable dielectric material to be cured. The curing chamber 20 also includes a vacuum pump 207 configured to remove process gases, purge gases, and other components from the curing chamber. It should be noted that the curing chamber 20 is an enclosed chamber when the access door 203 is in a closed position, i.e., the access door 203 in the closed position seals the curing chamber 20 to prevent ambient air from entering the curing chamber 20, thereby affecting the curing temperature and atmosphere conditions of the curing chamber. In some embodiments, the substrate rack 205 of the curing chamber 20 can have a number of slots sufficiently large for receiving and curing a corresponding number of substrates that have been processed by the process chambers 102. In an embodiment, the plurality of heating wires 201 can provide a uniform distribution of heated air to each slot for curing all substrates concurrently. In an embodiment, each slot has a heating element configured to control a temperature of that slot, i.e., the temperature of each slot in the curing chamber can be controlled individually by its associated heating element. In an embodiment, the heating element is a resistive heating element formed by a metal or including a metallic material having a defined relationship between temperature and resistivity and controlled by a dc current or ac current with an electrical waveform.

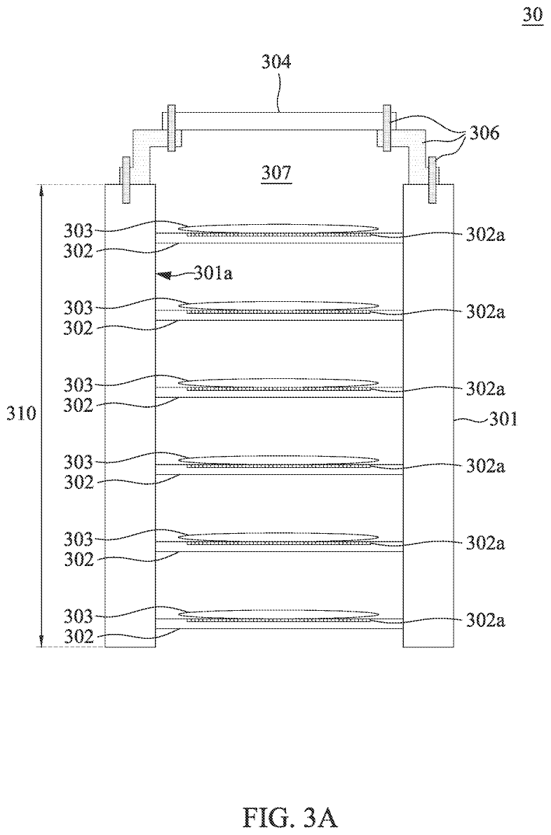

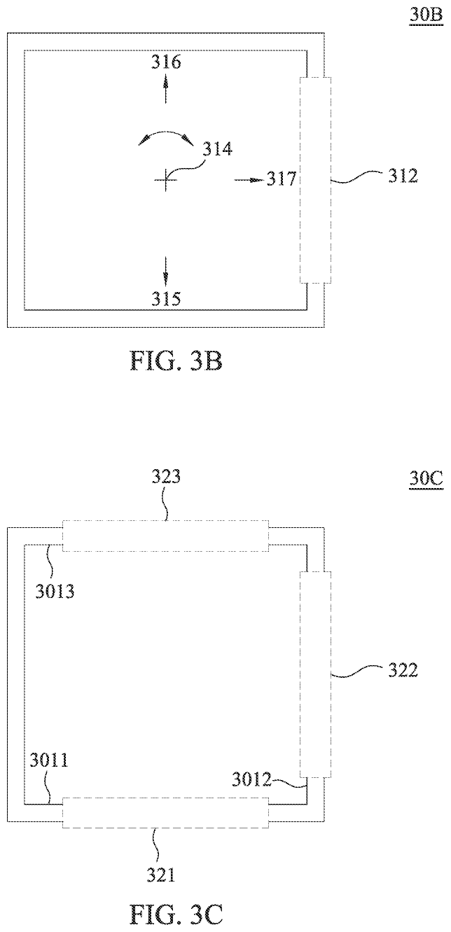

FIG. 3A is a simplified cross-sectional view of a cooling station 30 according to an embodiment. Referring to FIG. 3A, the cooling station 30 includes a housing 301, a plurality of shelves 302 attached to an inner wall surface 301a of the housing 301 and configured to provide support to a plurality of substrates 303, and a shelter plate 304 disposed on an upper side of the housing 301. In an embodiment, the housing 301 has an open upper side and an open lower side, so that air may flow from the upper side to the lower side or vice versa. It should be noted that the upper side and lower side of the cooling station are open whereas the curing chamber has a top wall and a bottom wall that enclose the curing chamber, i.e., the cooling station is an open enclosure where air can flow in and out through the upper side and the lower side, so that it has the pressure of the atmosphere. In one example, hot air may enter the cooling station 30 through the lower side and exit the cooling station 30 through the upper side. In contrast, the curing chamber 106 or 20 is a sealed enclosure to have a pressure different from the atmosphere pressure. In an embodiment, the shelter plate 304 is removably mounted to the upper side of the housing 301 through a fastening member 306. In an embodiment, the fastening member 306 includes threaded nuts and bolts configured to mount the shelter plate 304 to a portion of the housing 301. In an embodiment, the fastening member 306 includes screws that allows an easy and quick assembly of the shelter plate 304 to the housing 301 and its removal from the housing 301. It should be noted that the fastening member 306 is attached to a portion of the upper side of the housing 301 so that an air gap 307 extends vertically between the upper side of the housing 301 and the shelter plate 304. In an embodiment, the shelter plate 304 is a square having a size of 20×20 cm² for a 300 mm (i.e., 11.8 inch) substrate. In an embodiment, the shelter plate 304 includes aluminum. In an embodiment, the entire housing 301 includes a material having a thermal conductivity equal to or less than 150 W/mK. In some embodiments, the housing may include lead with a thermal conductivity of about 35 W/mK. In some embodiments, the housing may include iron having a thermal conductivity of about 80 W/mK. In some other embodiments, the housing may include platinum having a thermal conductivity of about 70 W/mK. In some other embodiments, the housing may include stainless steel having a thermal conductivity of about 15 W/mK. In yet some other embodiments, the housing may include glass having a thermal conductivity of about 0.8 W/mK. In various implementation, the shelter 304 is configured to function as a passive heating member for preventing upper slot cooling.

In an embodiment, the inner region of the cooling station 30 has a cross-sectional square or rectangular shape. Each side of the inner region of the cooling station is designed to accommodate 300 (i.e., 11.8 inch) mm, 450 mm (i.e., 17.7 inch) substrates or substrates having other dimensions. In an embodiment, the cooling station 30 has a height 310 that is relatively large, such that a large number of shelves 302 can be formed in the cooling station to accommodate a number of substrates that have been cured from the curing station 103. This is a case where the substrate process system 10 has more than one curing chamber 103 for curing a large quantity of batches of substrates having a flowable dielectric material deposited thereon. In an embodiment, each of the shelves 302 includes a heating element 302a configured to control temperature of an associated substrate deposited thereon. In an embodiment, the heating element 302a includes a heated plate. In an embodiment, the heating element 302a includes an electrically conductive material arranged spirally on a surface of the shelf and electrically isolated from the substrate by a dielectric layer. In an embodiment, the heating element 302a includes a polymer film having an electrically conductive circuit disposed on the surface of the polymer film and electrically insulated by the polymer film. In an embodiment, each of the shelves 302 includes a temperature sensor (e.g., a thermistor or thermocouple) disposed on its upper surface and configured to measure a temperature of the substrate disposed thereon and configured to control the heating level of the heating element 302a. Each temperature sensor provides measured temperature information of a corresponding substrate to a processing unit (not shown), so that the processing unit can control the temperature of each substrate individually. In one implementation, the individual heating elements 302a can be individually controlled at one or more temperatures. In another implementation, the individual heating elements 302a can be collectively controlled at one or more temperatures. By providing these controllable heating elements, temperature provided to the substrates 303 can be controlled to address the aforementioned condense accumulation on the substrates 303 with time passing. The heating element 302a may be referred to as active heating in accordance with the disclosure such that temperature are actively controlled for the individual substrates.

In an embodiment, the cooling station 30 includes an access door 308 that can be slidably open and close for receiving or removing substrates. In an embodiment, the cooling station 30 is rotatable around a vertical axis, so that the access door can be facing the transfer chamber, the curing chamber, or the FOUPs. In an embodiment, the housing 301 of the cooling station 30 has a square-shaped or rectangular-shaped cross section and includes a plurality of access doors each disposed at a side surface of the cooling station 30 for receiving or removing substrates.

FIG. 3B is a simplified top plan view of a cooling system 30B according to an embodiment. Referring to FIG. 3B, the cooling system 30B includes a squared-shaped or rectangular-shaped inner chamber having four vertical walls. In an embodiment, each wall has a dimension relatively large to accommodate substrates in the lateral or horizontal direction. In an embodiment, the cooling system 30B has an access door 312 operable in an open position and in a closed position for loading and unloading substrates. In an embodiment, the cooling system 30B is rotatable around a vertical axis 314 to be in a first position 315 for loading or unloading substrates from and to the FOUPs, a second position 316 for loading or unloading substrates from and to the transfer chamber, and a third position 317 for receiving the cured substrates from the curing station.

FIG. 3C is a simplified top plan view of a cooling system 30C according to another embodiment. Referring to FIG. 3C, the cooling system 30C includes a squared-shaped shaped or rectangular-shaped inner chamber having four vertical walls. In an embodiment, each wall has a dimension relatively large to accommodate substrates in the lateral or horizontal direction. In an embodiment, the cooling system 30C has a first access door 321 arranged in a first side 3011 of the housing 301 facing the FOUPs and operable in an open position and in a closed position for loading and unloading substrates from and to the FOUPs, a second access door 322 arranged in a second side 3012 of the housing 301 facing the cooling station 106 and operable in an open position and in a closed position for transferring cured substrates to the cooling station, and a third access door 323 arranged in a third side 3013 of the housing 301 facing the transfer chamber 103 and operable in an open position and in a closed position for loading and unloading substrates from and to the load lock chamber 104.

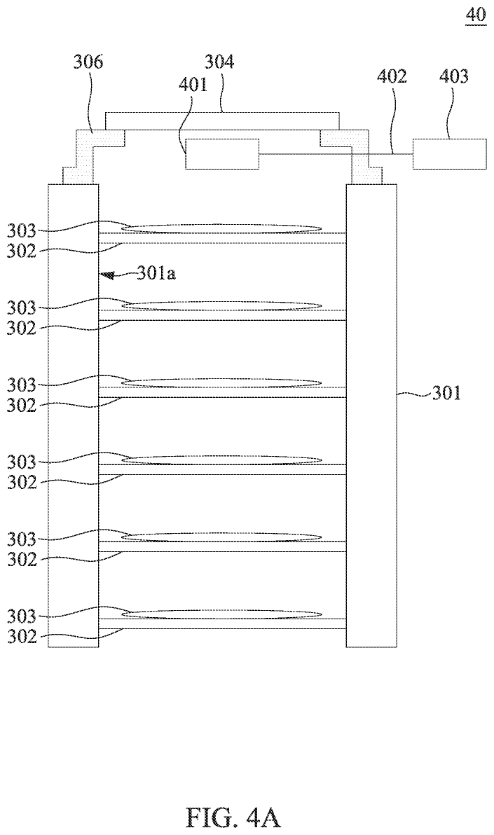

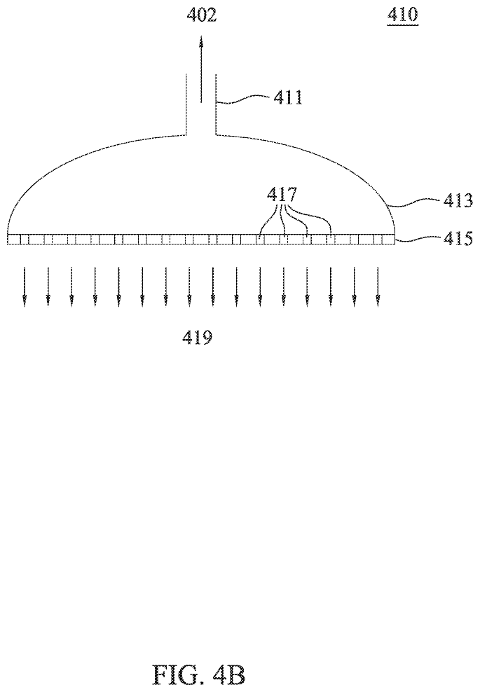

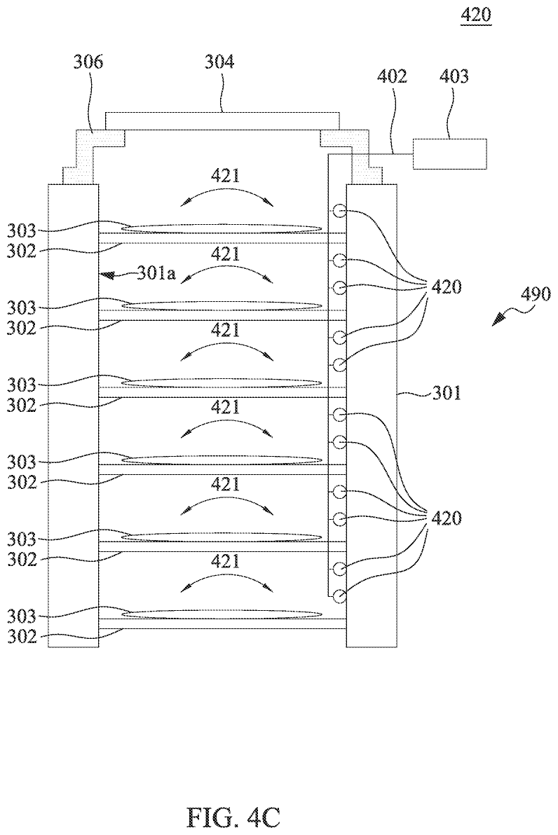

FIG. 4A is a simplified cross-sectional view of a cooling station 40 according to an embodiment. The cooling station 40 is substantially similar to the cooling station 30 with the difference that it further includes an airflow structure. Accordingly, description provided in relation to the elements illustrated in FIG. 3 is applicable to the elements illustrated in FIG. 4 as appropriate. Referring to FIG. 4A, the cooling station 40 includes an airflow structure 401 configured to deliver a temperature-controlled air (i.e., the temperature of the air is controlled) to control temperature inside the cooling station. In an embodiment, the airflow structure 401 includes a conduit 402 coupled to an air source 403 that is configured to supply a temperature-controlled air to the airflow structure. In an embodiment, the temperature-controlled air supplied by the air source 403 is in a range between about 20° C. and 100° C., in a range between 40° C. and 80° C., and in a range between 45° C. and 65° C. The temperature-controlled air may include nitrogen, argon, or XCDA dry air. In an embodiment, the airflow structure 401 includes a temperature sensor (not shown) configured to measure a temperature of the temperature-controlled air exiting the airflow structure 401. In some embodiments, the airflow structure is disposed below the shelter plate 304 and configured to operate as an air curtain, e.g., an air curtain showerhead or a cylindrical air curtain. It should be noted that in some implementations, each of the shelves 302 may include a heating element like 302a shown in FIG. 3A, which is configured to control temperature of an associated substrate deposited thereon.

FIG. 4B is a simplified cross-sectional view of a showerhead 410 according to an embodiment. Referring to FIG. 4B, the showerhead 410 is a part of the airflow structure 401 disposed below the shelter plate 304 and configured to supply a temperature-controlled air in a vertical direction (the top-to-bottom direction) to the inside of the housing 301. The showerhead 410 includes a stem 411 having a first end attached to the conduit 402 and a second end opposite the first end. The showerhead 410 also includes a back plate 413 attached to the second end of the stem 411, and a face plate 415 attached to the back plate 413. The face plate 415 includes a plurality of holes 417 that are distributed evenly or in a regular arrangement throughout the face plate in various patterns (e.g., a honey comb or concentric spiral pattern). The showerhead 410 directs a temperature-controlled air 419 from the air source 403 in a vertical direction to the inside of the housing 301. The showerhead 410 may be referred to as passive heating in that it aids air flow for better temperature control within the cooling station.

FIG. 4C is a simplified cross-sectional view of a cylindrical air curtain structure 490 according to an embodiment. Referring to FIG. 4C, the cylindrical air curtain structure 490 is a part of the airflow structure 401 and coupled to the air source 403 through the conduit 402. The cylindrical air curtain structure 490 includes a plurality of air pipes 420 arranged along the inner wall surface 301a of the housing 301. Each of the air pipes 420 includes at least one outlet and is configured to supply air in a circulation 421 from left-to-right or from right-to-left to control a temperature of the inside of the housing 301.

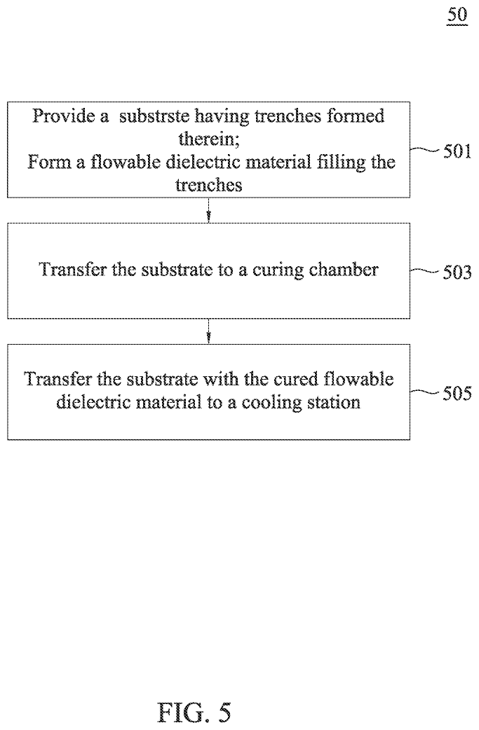

FIG. 5 is a simplified flowchart of a method 50 of controlling a temperature of a substrate having a cured dielectric material deposited thereon according to an embodiment. Referring to FIG. 5, the method 50 includes, at step 501, providing a substrate having trenches formed therein, and forming a flowable dielectric material on the substrate filing the trenches. The flowable material layer may be formed by a flowable chemical vapor deposition (FCVD) process. In an embodiment, depositing a flowable dielectric material involves exposing the substrate to gaseous reactants including a dielectric precursor and an oxidant. In some embodiments, the flowable dielectric material is a silicon and nitrogen-containing material, such as silicon nitride or silicon oxynitride deposited by introducing vapor phase reactants to the process chamber. The nitrogen may come from a silicon and nitrogen-containing precursor, e.g., trisilyamine (TSA) or disilylamine (DSA), a nitrogen precursor, e.g., ammonia (NH₃), or a nitrogen-containing gas, e.g., N₂, NH₃, NO, NO₂, or N₂O. At step 503, the method 50 includes transferring the substrate including the formed flowable dielectric material into a curing chamber where a curing process is performed. In an embodiment, the curing process includes submitting the formed flowable dielectric material to a treatment at a temperature in a range of about 25° C. to about 200° C., in a range of about 35° C. to about 55° C., in range of about 40° C. to about 50° C. under an ozone atmosphere and a pressure in a range of 1 atmosphere to about 20 atmospheres. The method also includes, at step 505, transferring the substrate including the cured flowable dielectric material into a cooling station. The cooling station has a predetermined temperature. In one implementation, the predetermined temperature is higher than the room temperature (typically between 15° C. and 30° C.) in the fabrication facility. In one example, the predetermined is higher than 15° C. In one implementation, the predetermined temperature is close to the temperature of a process chamber (e.g., one of the process chambers 102 in FIG. 1A) and the temperature of a curing chamber (e.g., one of the curing chambers 103 in FIG. 1A). The cooling station includes a housing having an open upper side and a shelter plate disposed over the open upper side. In an embodiment, the cooling chamber includes an airflow structure coupled to an external air source for controlling a circulation of a temperature-controlled air supplied by the air source.

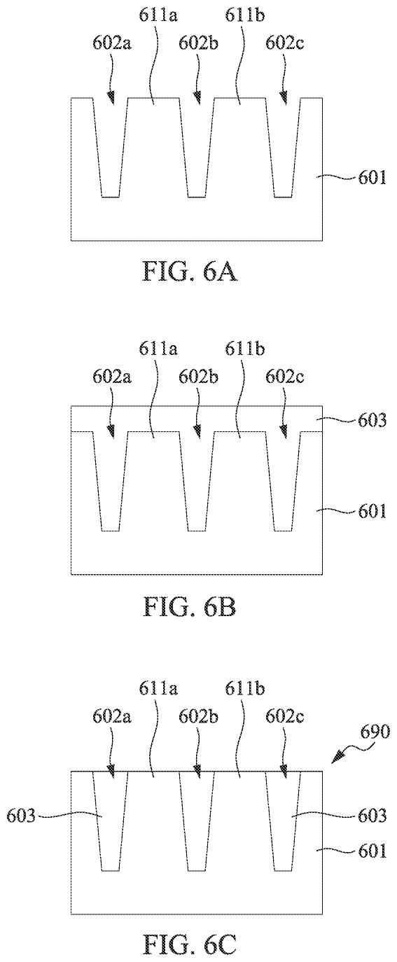

FIGS. 6A to 6C are simplified cross-sectional views of a portion of a substrate in various stages of the process illustrated in FIG. 5. Referring to FIG. 6A, a substrate 601 having multiple trench structures 602a, 602b, and 602c is provided. In the example of FIG. 6A, the substrate 601 may be a silicon substrate. In other examples, the substrate 601 may have a plurality of layers including, e.g., silicon oxide, silicon germanium, doped or undoped polysilicon, silicon-on-insulator, silicon nitride, doped silicon, germanium, glass, gallium nitride, gallium arsenide. The substrate 601 can have various sizes, such as 300 mm, 450 mm diameter substrate. The trench structures 602a, 602b, and 602c are formed in the substrate 601 by an etching process, e.g., a dry plasma etching process. Three-dimensional (3D) structures 611a and 611b are interposed between two of the trench structures 602a, 602b, and 602c. The 3D structures 611a and 611b are 3D channel structures of non-planar transistors (i.e., 3D transistors or multi-gate field-effect transistors) that are in contact with gates. In one example, the 3D structures 611a and 611b are fin structures of fin field-effect transistors (FinFETs). In another example, 3D structures 611a and 611b are 3D channel structures of gate-all-around field-effect transistors (GAA FETs). It should be understood that these examples are not intended to be limiting. In one implementation, the trench structures 602a, 602b, and 602c and the 3D structures 611a and 611b may be formed by patterning a photoresist layer on the substrate using photolithography processes and selectively etching the substrate. Referring to FIG. 6B, a flowable dielectric material 603 is deposited on the substrate filling the trench structures 602a, 602b, and 602c. In an embodiment, the flowable dielectric material 603 may include oxynitride. In an embodiment, a gas mixture including a silicon-containing material and a nitrogen containing precursor is provided into the process chamber 102 at a predetermined flow rate and within a predetermined temperature range to maintain the flowable dielectric material 603 in a flowable state (liquid phase). After the flowable dielectric material 603 is deposited, the substrate is transferred to the curing chamber 103 to remove moisture and other volatile components to form a solid dielectric material. In an embodiment, a batch of substrates are processes in the process chamber, and the curing temperature of each individual processed substrate can be controlled in the curing chamber. After the curing process is complete, the cured substrate is transferred to the cooling station 106 shown in FIG. 1A for cooling before being unloaded to the FOUPs or pre-heated again prior to being transferred back to the process chamber 102 for subsequent processing. In one example, the cured substrate may be submitted to a chemical-mechanical polishing (CMP) process to obtain the structure as shown in FIG. 6C. As shown in FIG. 6C, the upper surface of the structure has been flattened or smoothed by the CMP process. It should be noted that subsequent processes may be further conducted using the structure shown in FIG. 6C as a basis. It should also be noted that although the example in FIGS. 6A-6C is directed to FinFET-related fabrication, the sprits described in the disclosure may be applied to the fabrication of other semiconductor devices such as GAA FETs as needed.

Embodiments of the present disclosure provide a cooling station. The cooling station includes a housing comprising a plurality of shelves configured to receive a plurality of substrates, a shelter plate disposed over an upper side of the housing and configured to reduce heat loss of an upper substrate of the plurality of substrates, and an airflow structure in the housing and configured to control an air circulation in the housing.

Embodiments of the present disclosure also provide a method. The method includes the following steps: providing a substrate; etching the substrate to form a plurality of 3D structures and a plurality of trench structures; forming, at a process chamber, a flowable material layer over the substrate; curing, at a curing chamber, the substrate including the flowable material layer; and transferring the substrate to a cooling station having a predetermined temperature.

Embodiments of the present disclosure also provide a method of cooling a flowable dielectric material. The method includes forming a flowable material layer on a substrate, transferring the substrate including the flowable material layer to a curing chamber for curing the flowable layer, and transferring the substrate after curing the flowable material layer to a cooling station. In an embodiment, the cooling station includes a housing having an open upper side, and an airflow structure disposed in the housing and configured to control a circulation of a temperature-controlled air in the inside of the housing.

The foregoing merely outlines features of embodiments of the disclosure. Various modifications and alternatives to the described embodiments will be apparent to those skilled in the art in view of the teachings herein. Those skilled in the art will appreciate that equivalent constructions do not depart from the scope of the present disclosure, and that they may make various changes, substitutions, and alterations herein without departing from the spirit and scope of the present disclosure.

What is claimed is:

1. An apparatus for semiconductor processing comprising:
a housing comprising a plurality of shelves configured to receive a plurality of substrates;
a shelter plate disposed over an upper side of the housing and configured to reduce heat loss of an upper substrate of the plurality of substrates; and
an airflow structure in the housing and configured to control an air circulation in the housing.

2. The apparatus of claim 1, wherein the housing comprises a polygonal cross-sectional shape.

3. The apparatus of claim 1, wherein the housing comprises a material having a thermal conductivity equal to or less than 150 W/mK.

4. The apparatus of claim 1, wherein the shelter plate is removably mounted to the upper side of the housing.

5. The apparatus of claim 1, wherein the shelter plate comprises aluminum.

6. The apparatus of claim 1, wherein the shelter plate is mounted to the upper side of the housing through a fastening member.

7. The apparatus of claim 1, wherein the airflow structure is disposed below the shelter plate and comprises a showerhead having a plurality of openings configured to deliver air in a direction from top to bottom of the housing.

8. The apparatus of claim 1, wherein the airflow structure comprises a plurality of openings disposed along an inner peripheral surface of the housing and configured to deliver air from left-to-right or right-to-left along the inner peripheral surface of the housing.

9. The apparatus of claim 1, wherein the plurality of shelves each comprise a heating element configured to heat an associated substrate to a predetermined temperature.

10. A method comprising:
providing a substrate;
etching the substrate to form a plurality of three-dimensional (3D) structures and a plurality of trench structures;
forming, at a process chamber, a flowable material layer over the substrate;
curing, at a curing chamber, the substrate including the flowable material layer; and
transferring the substrate to a cooling station having a predetermined temperature.

11. The method of claim 10, wherein the predetermined temperature is higher than 15° C.

12. The method of claim 10, wherein the predetermined temperature is between a temperature of the process chamber and a temperature of the curing chamber.

13. The method of claim 10, wherein the cooling station comprises:
a housing comprising a plurality of shelves configured to receive a plurality of substrates;
a shelter plate disposed over an upper side of the housing and configured to reduce heat loss of an upper substrate of the plurality of substrates; and
an airflow structure in the housing and configured to control an air circulation in the housing.

14. The method of claim 13, wherein the housing comprises a material having a thermal conductivity equal to or less than 150 W/mK.

15. The method of claim 13, each of the plurality of shelves comprises a heating element.

16. The method of claim 10, wherein forming the flowable material layer comprises a flowable chemical vapor deposition (FCVD) process.

17. A method comprising:
forming a flowable material layer on a substrate;
transferring the substrate including the flowable material layer to a curing chamber for curing the flowable layer; and
transferring the substrate after curing the flowable material layer to a cooling station, wherein the cooling station comprises a housing having an open upper side, and an airflow structure disposed in the housing.

18. The method of claim 17, wherein forming the flowable material layer comprises a flowable chemical vapor deposition (FCVD) process.

19. The method of claim 17, further comprising mounting a shelter plate over the open upper side of the housing through a fastening member.

20. The method of claim 17, further comprising controlling an air circulation in the housing using the airflow structure.
